(19) United States
(12) Patent Application Publication
(10) Pub. No.: US 2014/0174499 A1
(43) Pub. Date: Jun. 26, 2014

(54) SOLAR THERMAL HELIOSTAT

(71) Applicants: Brian M. Fitzgerald, Cazenovia, NY (US); John D. Zalewski, Liverpool, NY (US); Franz Faschinger, Lannach (AT); Richard A. Bakowski, Warners, NY (US); Philipp Ebner, Lannach (AT); David W. Wenthen, Rochester Hills, MI (US); Burke Smith, Romeo, MI (US); Peter M. Jacobsen, Oakland, MI (US)

(72) Inventors: Brian M. Fitzgerald, Cazenovia, NY (US); John D. Zalewski, Liverpool, NY (US); Franz Faschinger, Lannach (AT); Richard A. Bakowski, Warners, NY (US); Philipp Ebner, Lannach (AT); David W. Wenthen, Rochester Hills, MI (US); Burke Smith, Romeo, MI (US); Peter M. Jacobsen, Oakland, MI (US)

(21) Appl. No.: 14/060,751

(22) Filed: Oct. 23, 2013

Related U.S. Application Data
(60) Provisional application No. 61/725,562, filed on Nov. 13, 2012.

(51) Int. Cl. F24J 2/54; H01L 31/052

(52) U.S. Cl. CPC F24J 2/5417; H01L 31/0525
USPC 136/246; 126/606

(57) ABSTRACT

A heliostat for reflecting sunlight toward a target includes a first structure supporting a mirror including inner and outer tubes being rotatable relative to one another. A first actuator includes an electric motor driving a reduction gearset to rotate one of the first tubes and rotate the mirror about a first axis. A second structure also includes inner and outer rotatable tubes. A second actuator includes a second electric motor driving a reduction gearset to rotate the mirror about a second axis.

### CROSS-REFERENCE TO RELATED APPLICATIONS

This application claims the benefit of U.S. Provisional Application No. 61/725,562 filed Nov. 13, 2012. The entire disclosure of the above application is incorporated herein by reference.

### FIELD

The present disclosure generally relates to solar energy collection and, more particularly, to a system for reliably and cost effectively constructing and calibrating a concentrated solar thermal energy system.

### BACKGROUND

This section provides background information related to the present disclosure which is not necessarily prior art.

Large scale collection of solar energy for use as an alternative power source to the fossil fuel industry has been desired for decades. Several governmental entities across the world have investigated the feasibility of large scale solar energy collection as a power source for public utilities or commercial use. Presently, the most efficient systems for harnessing solar energy and converting the energy into electrical power for general use is through the use of a concentrated solar thermal (CST) power generation system. CST systems rely on concentrated sunlight to generate power. The concentrated sunlight is typically provided from a field of heliostat mirrors that reflect sunlight on a target area of a solar thermal tower. The concentrated solar energy may be converted into electrical energy through a photovoltaic cell, by heating water to create steam that drives a turbine, or any other suitable method. The concentrated solar energy may be stored in a thermal mass and converted to a more user friendly form at a later time.

To generate sufficient power, a CST system may include several hundred or several thousand heliostats spaced apart from one another in a field. Each heliostat includes a mirror that must be accurately positioned to focus the sunlight on the target area of the tower. Due to the rotation of the earth about its axis as well as the rotation of the earth about the sun, and mechanical system tolerances, challenges exist relating to accurately and consistently controlling each heliostat to remain targeted. The efficiency of the solar power generation is directly related to the accuracy to the concentration of the solar energy. For example, it is desirable to maintain an azimuth orientation as well as an elevation orientation within 0.10 degrees of a target position. Misalignment of a mirror or mirrors causes the reflected light to miss the target area thereby reducing the concentration of solar energy. Known mirror heliostats typically track the sun through the use of known solar positions being programmed into each heliostat and the mirror being moved according to the known positions. Due to inaccuracies that may exist in the positioning system of the heliostat mechanism, the actual orientation of the mirror of the heliostat may not be at the desired angular orientation and the reflected sunlight would not be aligned toward the targeted area of the solar power tower. In addition, it may also be a challenge to maintain a desired mirror orientation once it has been initially set.

Typical mirror heliostat devices are very expensive to manufacture and because hundreds or thousands of heliostats are used in a single concentrated solar thermal power generation system, the heliostats constitute the majority of the cost of the solar energy collection system. Known methods for initially installing and targeting the heliostats also contribute to the high cost of starting power generation. For example, many known systems require a predetermined minimum magnitude of sunlight to be reflected from the heliostat mirror to initially target the heliostat. Accordingly, these efforts may only occur during daylight hours when inclement weather is not present. It may take months to initially target each of the heliostats in a given concentrated solar thermal system field.

Additional challenges relate to minimizing the power required to move the heliostat mirror and defining a robust structure sufficient to support the mirror and withstand natural forces such as wind gusts.

Concerns also exist regarding the cost and logistics relating to the control of each heliostat, a power supply to the heliostat positioning system, and the infrastructure required for these systems to properly operate. For example, it may be undesirable to directly wire each heliostat to one another or wire each heliostat to a common power supply or heliostat control unit as the distance between heliostats on the opposite side of a field may be several miles.

### SUMMARY

This section provides a general summary of the disclosure, and is not a comprehensive disclosure of its full scope or all of its features.

A heliostat for reflecting sunlight toward a target includes a first structure supporting a mirror including inner and outer tubes being rotatable relative to one another. A first actuator includes an electric motor driving a reduction gearset to rotate one of the first tubes and rotate the mirror about a first axis. A second structure also includes inner and outer rotatable tubes. A second actuator includes a second electric motor driving a reduction gearset to rotate the mirror about a second axis.

A heliostat for reflecting sunlight toward a target includes a first structure for supporting a mirror including a first outer tube concentrically supported for rotation on a first inner tube. One of the first inner tube and the first outer tube is restricted from movement and coupled to the ground. A first actuator includes a first electric motor driving a reduction gearset for rotating the other of the first inner and outer tubes relative to the ground to rotate the mirror about a first axis. A second structure supports the mirror and includes a second outer tube concentrically supported for a rotation on a second inner tube. One of the second inner and outer tubes is fixed to the other of the first inner and outer tubes. A second actuator includes a second electric motor driving a reduction gearset. The second actuator rotates the other of the second inner and outer tubes relative to the one of the second inner tube and the second outer tube to rotate the mirror about a second axis.

A heliostat for reflecting sunlight toward a target includes a mirror mounted to a frame. A drive mechanism coupled to the frame orients the mirror relative to the sun. The drive mechanism includes a compound planetary gearset driving a worm gearset. The compound planetary gearset includes a sun gear, a first ring gear, a second ring gear, and a plurality of pinion gears each being in a constant meshed engagement with the sun gear, the first ring gear and the second ring gear. The first ring gear has fewer teeth than the second ring gear.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic depicting a solar thermal heliostat in conjunction with an exemplary solar thermal energy collection system;

FIG. 2 is a fragmentary respective view of a solar heliostat;

FIG. 3 is a fragmentary exploded perspective view of the solar thermal heliostat depicted in FIG. 2;

FIG. 4 is another fragmentary exploded perspective view depicting the remaining portion of the heliostat shown in FIGS. 2-3;

FIG. 5 is a fragmentary sectional view of a portion of the heliostat;

FIG. 6 is a fragmentary sectional view of another portion of the heliostat;

FIG. 7 is a fragmentary sectional view of another portion of the heliostat;

FIG. 8 is a fragmentary sectional view of another portion of the heliostat;

FIG. 9 is a sectional view of a frame and mirror;

FIG. 10 is fragmentary perspective view depicting a puck and a mirror; and

FIG. 11 is a schematic depicting a photovoltaic cell battery charging system for a heliostat.

Corresponding reference numerals indicate corresponding parts throughout the several views of the drawings.

### DETAILED DESCRIPTION

Example embodiments will now be described more fully with reference to the accompanying drawings.

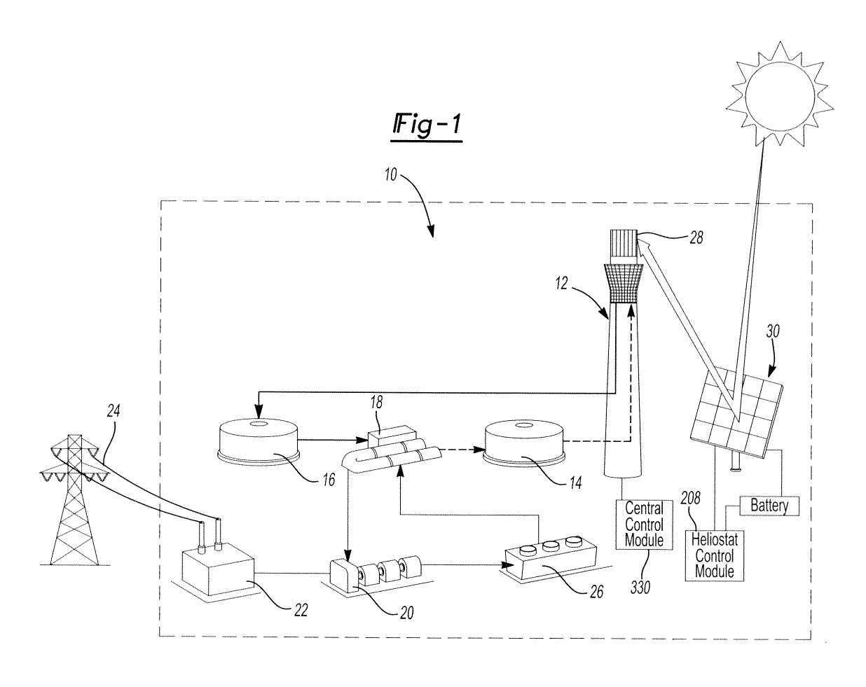

FIG. 1 provides a schematic of an exemplary concentrated solar thermal energy collection system identified at reference numeral 10. System 10 includes a solar thermal tower 12 in fluid communication with a cold fluid storage tank 14 and a heated fluid storage tank 16. Heated fluid storage tank 16 provides energy to a steam generator 18. Steam is provided to a steam turbine and electric generator 20. Electrical energy may be provided to a substation 22 for distribution to a plurality of power lines 24. A cooling tower 26 is in communication with steam generator 18 and steam turbine 20 to return cooled heat transfer fluid to cold storage tank 14. A plurality of heliostats 30 are spaced apart from one another and oriented to reflect sunlight toward a target 28 positioned on solar thermal tower 12.

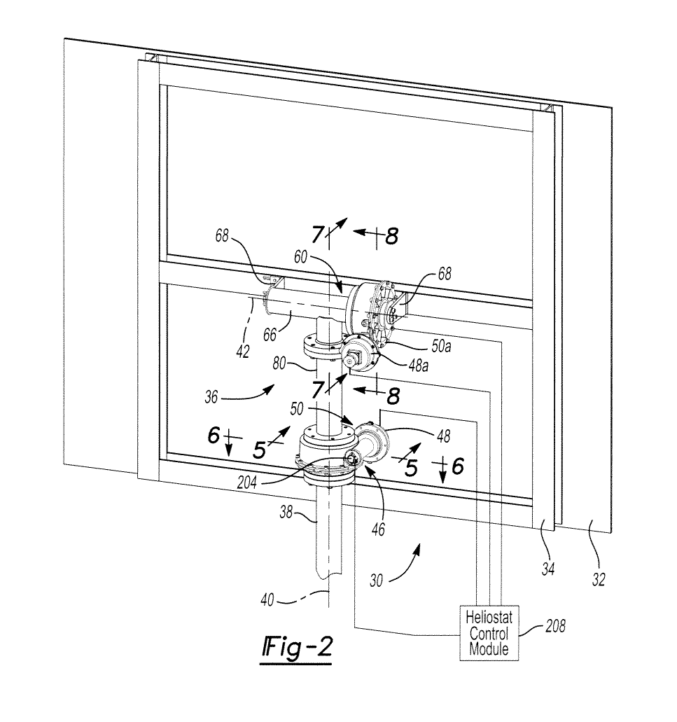

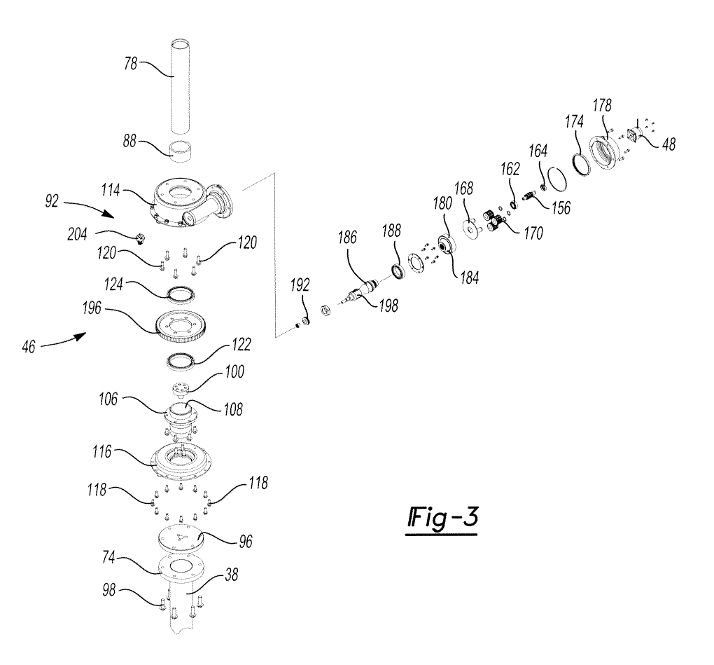

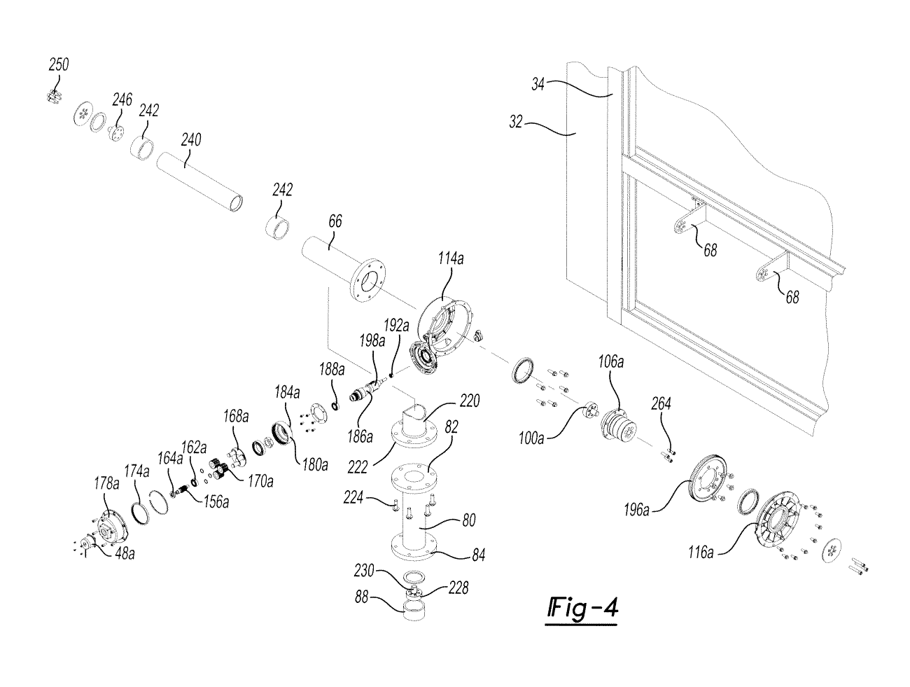

As shown in FIGS. 1-2, each heliostat 30 includes a mirror 32 fixed to a frame 34. A solar tracking mechanism 36 interconnects frame 34 with a post 38 that is fixed to the ground. A guard rail (not shown) or some other easily attainable steel beam may be pile driven into the ground. Post 38 may be fixed to the guard rail. Actuation of tracking mechanism 36 may cause frame 34 to rotate about a first axis 40 and/or a second orthogonal axis 42. More particularly, a first alignment mechanism 46 is operable to rotate frame 34 about first axis 40. First alignment mechanism 46 includes an electric motor 48 and a drivetrain 50 for rotating an outer tube 80 about first axis 40. In similar fashion, a second alignment mechanism 60 is provided to rotate frame 34 about second axis 42. Second alignment mechanism 60 includes an electric motor 48a driving a drivetrain 50a to rotate an outer tube 66 fixed to frame 34 via brackets 68.

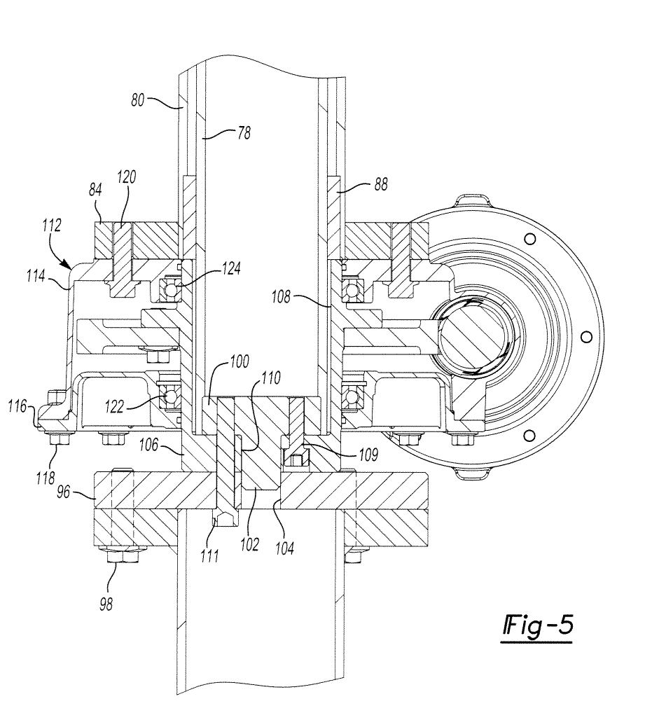

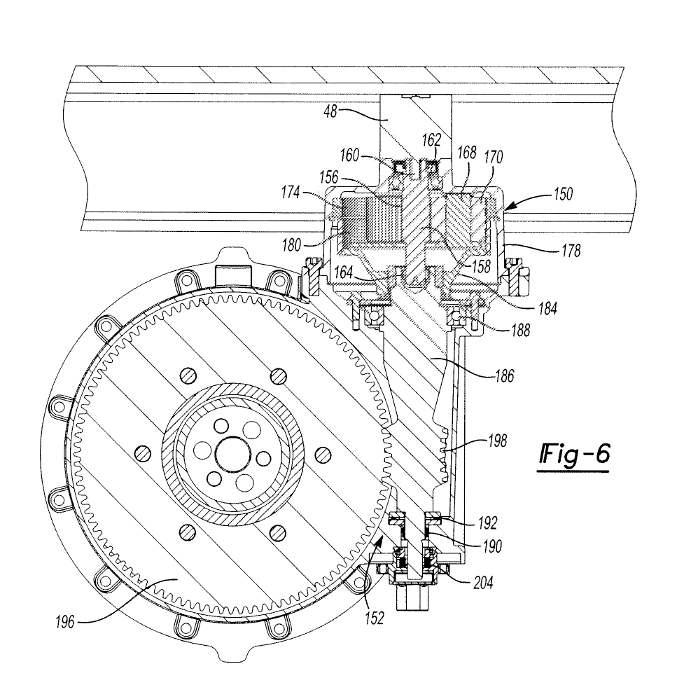

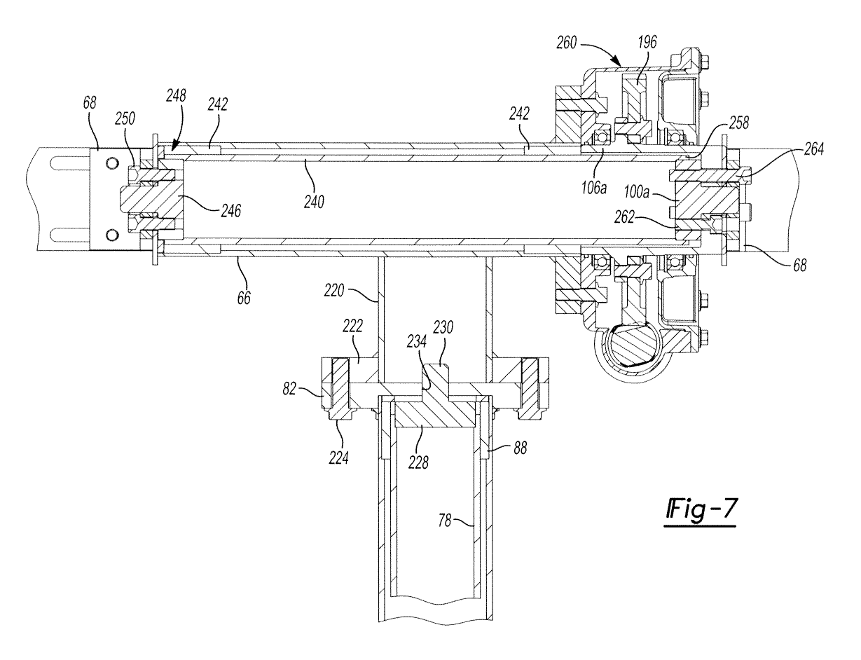

First alignment mechanism 46 is fixed to a flange 74 fixed to post 38. First alignment mechanism 46 includes an inner tube 78 concentrically aligned with outer tube 80. Terminal ends of outer tube 80 are fixed to an upper flange 82 and a lower flange 84. Bushings or bearings 88 concentrically align inner tube 78 with outer tube 80 and allow relative rotation therebetween. First alignment mechanism 46 includes a first actuator 92 operable to rotate outer tube 80 relative to inner tube 78. A plate 96 is fixed to flange 74 via a plurality of fasteners 98. A coupling 106 abuts plate 96 and includes a pocket 108 in receipt of inner tube 78. An adapter 100 is press fit within a counterbore formed within one end of inner tube 78 and positioned within pocket 108. A plurality of fasteners 109 fix coupling 106 to adapter 100. Fasteners 111 (FIG. 5) fix plate 96 to adapter 100. Adapter 100 includes a pin 102 extending through an aperture 104 of plate 96. Pin 102 extends through an aperture 110 of coupling 106 to align outer tube 80 and inner tube 78 with post 38.

First actuator 92 includes a housing assembly 112 including a first half 114 fixed to a second half 116 by a plurality of fasteners 118. Electric motor 48 and drivetrain 50 are positioned within housing 112. Housing 112 is rotatably supported on coupling 106 by a pair of bearings 122, 124. Based on this arrangement, post 38 remains non-rotatably fixed to the ground during operation of heliostat 30. Plate 96, adapter 100 and coupling 106 remain fixed to post 38. Fasteners 120 fix housing 112 to flange 84, housing 112, flange 82, outer tube 80 and flange 84 to rotate as a unit relative to post 38 during energization of first actuator 92.

First actuator 92 includes electric motor 48 and drivetrain 50 positioned within housing 112. Drivetrain 50 includes a primary gear reducer 150 configured as a two-stage compound-coupled epicyclical planetary gearset driving a worm and gear final drive set 152. Planetary gearset 150 includes a sun gear 156 integrally formed on an input shaft 158 that is fixed for rotation with an output shaft 160 of electric motor 48. Input shaft 158 is supported for rotation by a roller bearing 162 and a needle bearing 164. Planetary gearset 150 includes a carrier 168 rotatably supporting a plurality of circumferentially spaced apart pinion gears 170. A first ring gear 174 is fixed to an end cap 178 forming a portion of housing 112. Each of pinion gears 170 are in constant meshed engagement with first ring gear 174 and sun gear 156. A second ring gear 180 is positioned adjacent to first ring gear 174 and in constant meshed engagement with each of pinion gears 170. Second ring gear 180 includes one to three more internal teeth than first ring gear 174. Second ring gear 180 functions as the output of planetary gearset 150. It is contemplated that planetary gearset 150 provides a reduction ratio of greater than 200:1. A yoke 184 is fixed for rotation with second ring gear 180.

Worm and gear final drive set 152 includes a worm shaft 186 having an enveloping worm gear 198 formed thereon. Worm shaft 186 is supported for rotation in housing 112 by a bearing 188 and another bearing 190. A thrust bearing or thrust washer 192 is provided to react the axial load applied to worm shaft 186. A cylindrical gear 196 is in constant meshed engagement with worm gear 198. The worm and gear final drive set 152 is configured to provide a final drive gear ratio of approximately 101:1. The combination of two-stage compound planetary gearset 150 and worm and gear final drive set 152 provides a total reduction ratio of greater than 20,000:1 with the least number of gear components thereby minimizing the necessary system input torque and power consumption.

Cylindrical gear 196 may be helical or spur if the thread lead angle of worm gear 198 is less than (4 degrees) without reducing the contact area between members significantly. The worm and gear final drive set 152 backlash and consequent axis rotation accuracy is controlled by the worm shaft and cylindrical final drive gear center distance and circular tooth thickness of both members. The use of cylindrical gear 196 with the enveloping worm gear 198 allows for the production of components within a strict tooth size tolerance (DIN 8 size tolerance) categorized into grades with composite roll inspection within the size range, selected and matched based on the measured center distance of the housing. The cylindrical gear can be laced through the body of the worm thread form at assembly for rapid production.

An encoder 204 is associated with worm shaft 186 to output a signal indicative of the position of mirror 32 along first axis of rotation 40. Encoder 204 may be a rather inexpensive and durable hall-type magnetic rotary encoder. The 101:1 final drive ratio permits the use of such an encoder, while still meeting the required targeting accuracy.

A heliostat control unit 208 is in receipt of the encoder signal and determines the angular position of mirror 32 on first axis 40 based on the signal and the geometrical relationship between worm gear 198 and gear 196. Heliostat control unit 208 is also in communication with electric motor 48 to selectively energize the motor and rotate mirror 32. It should be appreciated that the enveloping worm and gear final drive set 152 is constructed such that a torque input applied to gear 196 will not rotate worm shaft 186. In other words, the worm and gear final drive set 152 may not be back driven. As such, first actuator 92 may be beneficially used to maintain the orientation of mirror 32 at a desired location once first alignment mechanism 46 has rotated frame 34 and mirror 32 to a desired angular position as determined by heliostat control unit 208.

Gear 196 includes teeth shaped as standard cylindrical or spur gear teeth while worm gear 198 is enveloping and also includes teeth having a helical lead angle less than or equal to four degrees. The intentional mismatch of a spur gear to a helical gear-shape eliminates backlash within the gearset to assure an increased positional accuracy and minimal change in mirror position once the angular orientation of the mirror has been set.

Second alignment mechanism 60 of heliostat 30 includes a vertically oriented stub shaft 220 having one end welded to a flange 222 and an opposite end fixed to outer tube 66. Flange 222 is rigidly mounted to flange 82 by a plurality of fasteners 224. An adapter 228 is fixed to an inner tube 240 and includes a pin portion 230 protruding through an aperture 234 extending through flange 82.

Second alignment mechanism 60 functions substantially similarly to first alignment mechanism 46 with the exception that outer tube 66 remains fixed while inner tube 240 may be rotated to change the angular position of mirror 32. Bushings 242 concentrically align outer tube 66 with inner tube 240 and allow relative rotation therebetween. An adapter 246 is fixed to an end 248 of inner tube 240. Fasteners 250 fix one of brackets 68 with adapter 246 such that bracket 68 rotates with inner tube 240.

Second actuator 260 is substantially the same as first actuator 92. As such, similar elements will be identified with like reference numerals including an “a” suffix. Coupling 106a is fixed to adapter 100a with a plurality of fasteners 262. Adapter 100a is fixed to an opposite end 258 of inner tube 240. Second actuator 260 is operable to rotate inner tube 240 about second axis 42. Fasteners 264 fix adapter 100a to the other bracket 68. Energization of electric motor 48a causes rotation of inner tube 240 relative to outer tube 66. Brackets 68, frame 34 and mirror 32 are rotated about second axis 42.

Heliostat control unit 208 is in receipt of a signal from encoder 204a indicative of the angular position of mirror 32 along second axis 42 Heliostat control unit 208 is operable to determine a target angular position for mirror 32 in relation to first axis 40 and second axis 42. To conserve energy, heliostat control unit 208 implements an incremental target positioning scheme as opposed to a continuous control. A frequency of incremental target positioning is based on the particular position of each mirror 32 in the heliostat field in relation to the target, the backlash of the drive mechanism, and the amount of energy available per unit time for actuator operation. Heliostat control unit 208 may also be programmed to position mirror 32 at an initial leading position where the reflected light may be less than optimally targeted but as the time of day changes, the reflection becomes targeted at a nominal position. A tolerance regarding a maximum trailing position may also be programmed within heliostat control unit 208 to allow the reflected rays to be less than optimally targeted for an amount of time as the time of day continues past the time at which the reflection was targeted to nominal. It is contemplated that electric motors 48, 48a are DC stepping motors. Heliostat control unit 208 implements intermittent pulse operation with solid state circuitry to minimize the total power required to properly align mirror 32.

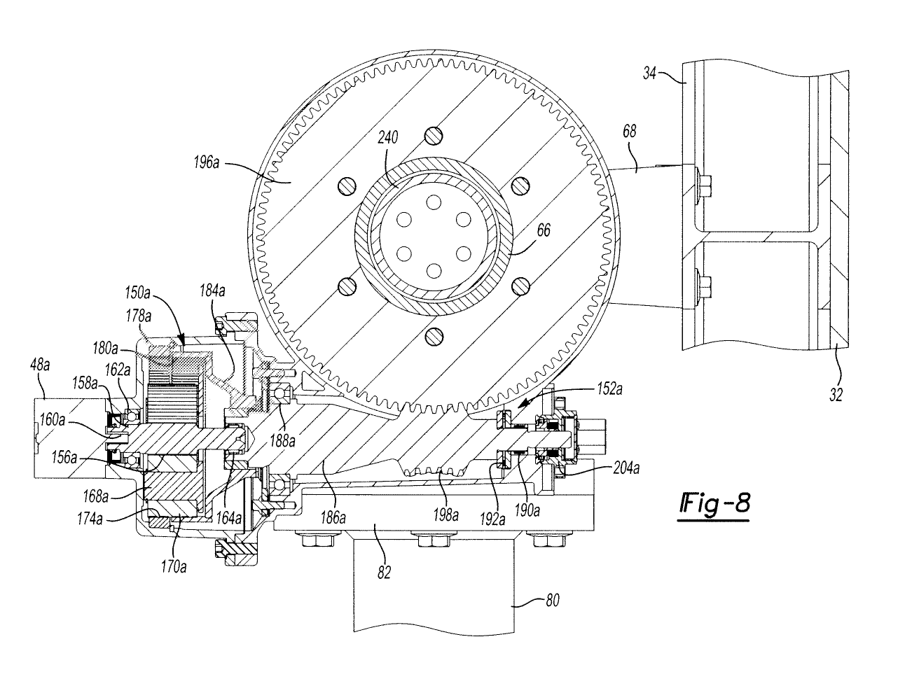

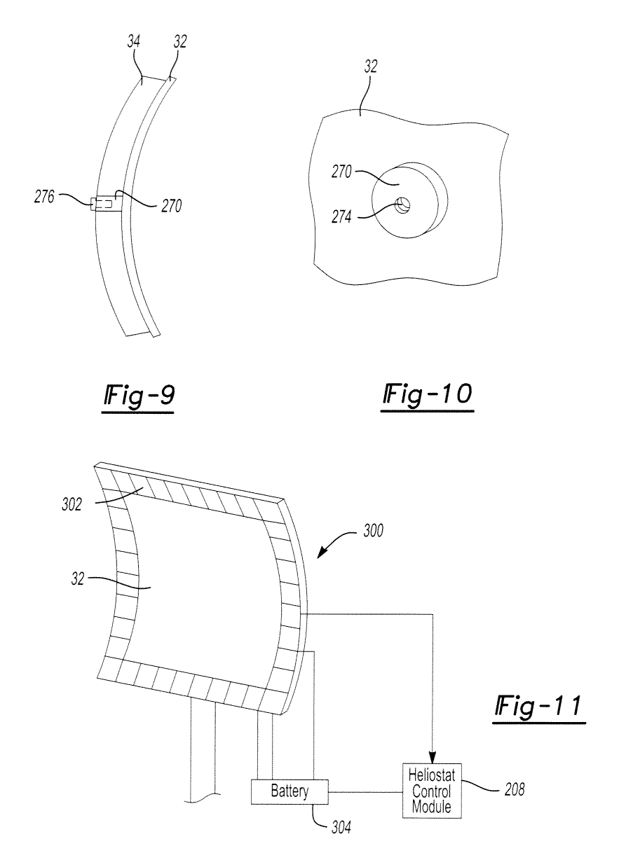

Mirror 32 is a single-piece monolithic mirror constructed from low iron grade glass with metallic plating for maximum reflectivity. As shown in FIGS. 9 and 10, frame 34 may include a parabolic concave shape. Mirror 32 is adhesive mounted to the parabolically shaped support frame 34 such that the mirror also defines a parabolic concave shape within the flexibility limits of the glass. This arrangement reduces the deflection losses of the solar light beam from flatness irregularities that may be imparted due to the glass tempering heat treatment process.

An optional center anchor 270 may be used to couple the mirror to the frame. It is contemplated that mirror 32 will be unloaded from shipping dunnage and handled throughout the assembly process with robotic automation using vacuum and pneumatic powered contact devices. The plated surface of the mirror and the face of support frame 34 will be coated with an adhesive bonding compound. Center anchor 270 may be constructed from an elastomeric material including a threaded insert 274. Center anchor 270 may be heated prior to assembly to accelerate the curing of the bonding adhesive upon placement at the rear center of the mirror. Mirror 32 may be positioned adjacent parabolic frame 34 and overflexed to assure that the center portion of the mirror contacts the frame during initial placement. Mirror 32 is aligned to frame 34 and pressed into final position. Anchor 270 is clamped to frame 34 using a threaded fastener 276 and the mirror to frame adhesive is allowed to cure. Alternative fastening techniques including the use of rivets, snap rings and other coupling devices are contemplated as being within the scope of the present disclosure.

As best depicted in FIG. 11, a photovoltaic energy storage system 300 includes a plurality of photovoltaic cells 302 positioned about the perimeter of mirror 32. Photovoltaic cells 302 provide electrical current to a battery 304 when sunlight strikes photovoltaic cells 302. Battery 304 may be electrically coupled to heliostat control unit 208 to provide energy for a full range of daily operations as well as emergency positioning of mirror 32 during night time hours. Energy from battery 304 may be used to power electric motors 48, 48a as well as heliostat control unit 208. Should it be necessary to return mirror 32 to a home position, it may be desirable to use ambient light energy at dawn or dusk to perform this manoeuver using electrical energy from photovoltaic cells 302. The battery backup power may be used for low energy heliostat control unit 208 operations and night time maintenance commands if necessary.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A heliostat for reflecting sunlight toward a target, comprising:
a mirror;
a first structure for supporting the mirror including a first outer tube concentrically supported for rotation on a first inner tube, one of the first inner tube and the first outer tube being restricted from movement and coupled to the ground;
a first actuator including a first electric motor driving a first reduction gearset, the first actuator rotating the other of the first inner and outer tubes relative to the ground to rotate the mirror about a first axis;
a second structure for supporting the mirror and including a second outer tube concentrically supported for rotation on a second inner tube, one of the second inner tube and the second outer tube being fixed to the other of the first inner and outer tubes; and
a second actuator including a second electric motor driving a second reduction gearset, the second actuator rotating the other of the second inner and outer tubes relative to the one of the second inner tube and the second outer tube to rotate the mirror about a second axis.

2. The heliostat of claim 1, wherein the first actuator includes a worm gearset driven by the first reduction gearset.

3. The heliostat of claim 2, further including a first housing containing the first reduction gearset and the worm gearset of the first actuator, the first housing rotating about the first axis when the first electric motor is energized.

4. The heliostat of claim 2, wherein the worm gearset of the first actuator includes a worm having teeth with a helical lead angle and a gear having spur teeth in meshed engagement.

5. The heliostat of claim 4, wherein the gear has an axis of revolution aligned with the first axis.

6. The heliostat of claim 5, wherein the gear is restricted from rotation.

7. The heliostat of claim 6, wherein the worm is simultaneously rotatable about a worm axis and the first axis.

8. The heliostat of claim 2, wherein the first reduction gearset of the first actuator includes a planetary gearset including a sun gear driven by the first electric motor, a first ring gear restricted from rotation, a second ring gear driving the worm gearset, and a pinion gear in constant meshed engagement with the sun gear, the first ring gear and the second ring gear.

9. The heliostat of claim 8, wherein the sun gear rotates about the same axis as a worm of the first actuator worm gearset.

10. The heliostat of claim 1, further including an encoder outputting a signal indicative of the rotary position of the mirror.

11. The heliostat of claim 9, wherein the encoder includes a Hall effect device is coupled to a worm of the first actuator worm gearset.

12. The heliostat of claim 1, wherein the first axis and the second axis extend perpendicular to each other.

13. The heliostat of claim 1, wherein the first outer tube is fixed to a first flange and the second outer tube is fixed to a second flange, the first and second flanges engaging one another and being fixed to each other.

14. The heliostat of claim 1, wherein the first and second actuators each include a worm gearset including a gear having an axis of rotation, the gear axes of rotation intersecting each other.

15. The heliostat of claim 1, further including a frame coupled to the second structure and an elastomeric anchor interconnecting the mirror and the frame, the anchor including a fastener to maintain a parabolic shape of the mirror.

16. The heliostat of claim 1, further comprising a solar power system including a photovoltaic cell mounted to the mirror such that energy output from the photovoltaic cell charges a battery, and wherein at least one of the first and second electric motors receives energy from the battery to rotate the mirror.

17. A heliostat for reflecting sunlight toward a target, comprising:
a frame;
a mirror mounted to the frame; and
a drive mechanism coupled to the frame to orient the mirror relative to the sun, the drive mechanism including an electric motor driving a compound planetary gearset and a worm gearset driven by the compound planetary gearset, the compound planetary gearset including a sun gear, a first ring gear, a second ring gear and a plurality of pinion gears each being in a constant meshed engagement with the sun gear, the first ring gear and the second ring gear, wherein the first ring gear has fewer teeth than the second ring gear.

18. The heliostat of claim 17, wherein the drive mechanism rotates the mirror about a first axis, the heliostat including a second drive mechanism for rotating the mirror about a second axis extending perpendicular to the first axis.

19. The heliostat of claim 17, further including an elastomeric anchor interconnecting the mirror and the frame, the anchor including a fastener to maintain a parabolic shape of the mirror.

20. The heliostat of claim 17, further comprising a solar power system including a photovoltaic cell mounted to the frame such that energy output from the photovoltaic cell charges a battery, wherein the electric motor receives energy from the battery to rotate the mirror.

21. The heliostat of claim 17, wherein the electric motor drives the sun gear, wherein the second ring gear drives the worm gearset, and wherein the worm gearset includes a worm having teeth with a helical lead angle and a gear having spur teeth in meshed engagement with the teeth of the worm, the gear being mounted for rotation with the mirror relative to the frame.

22. The heliostat of claim 17, wherein the gear has an axis of revolution aligned with the first axis.
